(19) United States
(12) Patent Application Publication
(10) Pub. No.: US 2025/0360455 A1
(43) Pub. Date: Nov. 27, 2025

(54) SYSTEM AND METHOD FOR CARBON CAPTURE IN A SEMICONDUCTOR FABRICATION FACILITY

(71) Applicant: Taiwan Semiconductor Manufacturing Company, LTD., Hsinchu (TW)

(72) Inventors: CHENG KUEI FU, TAINAN (TW); Y.D. FAN, TAINAN (TW); CHUN-CHI TSENG, TAOYUAN (TW); CHUN WEI, TAICHUNG (TW); SHU MAN HUANG, PINGTUNG COUNTY (TW)

(21) Appl. No.: 18/671,343

(22) Filed: May 22, 2024

(51) Int. Cl. B01D 53/14; B01D 53/02; B01D 53/18; B01D 53/62; B01D 53/78; C02F 1/00; C02F 1/52; C02F 1/66; C02F 103/04; C02F 103/34; C23C 16/02

(52) U.S. Cl. CPC B01D 53/1418; B01D 53/02; B01D 53/1475; B01D 53/1493; B01D 53/18; B01D 53/62; B01D 53/78; C02F 1/5236; C02F 1/66; C23C 16/0227; B01D 2252/103; B01D 2252/30; B01D 2253/106; B01D 2257/504; B01D 2257/708; B01D 2258/0216; C02F 2001/007; C02F 2103/04; C02F 2103/346

(57) ABSTRACT

Semiconductor device fabrication processing produces a carbon dioxide-containing waste gas and an aqueous solution containing calcium ions. To perform carbon capture, the carbon dioxide-containing waste gas and the aqueous solution containing calcium ions are reacted to form solid calcium carbonate. A carbon capture apparatus for a semiconductor fabrication facility includes: a buffer tank operatively connected to receive aqueous waste water from a fluorine removal system of the semiconductor fabrication facility that reacts fluorine-containing waste water with calcium chloride, the buffer tank holding aqueous alkaline waste water containing calcium ions; and a reactor configured to capture carbon from waste gas generated by the semiconductor fabrication facility by reacting carbon dioxide in the waste gas with the aqueous alkaline waste water containing calcium ions which is transferred to the reactor from the buffer tank to produce solid calcium carbonate.

### BACKGROUND

The following relates to environmentally friendly semiconductor fabrication facilities, carbon capture in semiconductor fabrication facilities, handling of waste water and waste gases in semiconductor fabrication facilities, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a carbon capture method processing waste water and waste gases generated by a semiconductor fabrication facility according to an embodiment.

FIG. 2 diagrammatically illustrates a carbon capture system of a semiconductor fabrication facility according to an embodiment.

FIG. 3 diagrammatically illustrates a carbon capture system of a semiconductor fabrication facility according to an embodiment.

FIG. 4 diagrammatically illustrates an isolation view of the gas aeration atomizer of the carbon capture system of FIG. 3.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor fabrication facilities employ a wide range of chemicals in diverse industrial-scale chemical reactions. Many of these reactions employ organic compounds and produce greenhouse gases as reaction byproducts, particularly carbon dioxide (CO₂). For example, semiconductor fabrication processes such as dry etching, chemical vapor deposition (CVD), physical vapor deposition (PVD), metalorganic vapor phase epitaxy (MOVPE), and so forth involve organic reactants or precursors, and commonly generate volatile organic compounds as waste products. Semiconductor facilities also utilize large quantities of deionized water, to the extent that deionized (DI) water (for example, ultrapure deionized water (UPDI) as a nonlimiting illustrative example of DI water) is usually manufactured on-site. UPDI manufacture includes removal of carbon components such as carbonate ions (CO₃²⁻) from the water, constituting further waste carbon byproduct.

The carbon waste generated by the semiconductor fabrication facility may ultimately be released to the atmosphere as carbon dioxide. However, atmospheric carbon dioxide absorbs and traps certain wavelengths of electromagnetic radiation, a process which has been identified as contributing to climate change (e.g., global warming).

Carbon capture techniques can be employed to capture some of this waste carbon byproduct to prevent its release into the atmosphere. However, performing carbon capture at the semiconductor fabrication facility involves shipping in additional chemicals to be used in performing the carbon capture. The additional delivered chemicals add overhead costs to operation of the semiconductor fabrication facility. The additional delivered chemicals also contribute to the chemical waste footprint of the semiconductor fabrication facility, by adding to the waste output of the semiconductor fabrication facility.

Embodiments disclosed herein provide for on-site carbon capture at a semiconductor fabrication facility, in which the chemicals used for the carbon capture processing are obtained from waste generated by the semiconductor fabrication facility. In a suitable approach, semiconductor device fabrication processing is performed at the semiconductor fabrication facility that produces a carbon dioxide-containing waste gas and an aqueous solution containing calcium ions. The carbon dioxide-containing waste gas and the aqueous solution containing calcium ions are reacted at the semiconductor fabrication facility to form solid calcium carbonate.

The semiconductor device fabrication processing is performed at the semiconductor fabrication facility to produce a semiconductor device (or batch of semiconductor devices). The semiconductor device(s) may, by way of some nonlimiting illustrative examples, include an integrated circuit (IC) or batch of ICs, a solid state memory device (e.g., DRAM, flash memory, et cetera) or batch thereof, a microelectromechanical system (MEMS) device or batch of MEMS devices, a combination thereof (e.g., an integrated circuit with integrated memory), or so forth.

The semiconductor device fabrication processing may directly contribute to the fabrication of the semiconductor device (in the sense of directly processing a semiconductor wafer), and/or the semiconductor device fabrication processing may constitute onsite manufacturing of chemicals used in the fabrication of the semiconductor device, and/or the semiconductor device fabrication processing may constitute processing of byproducts of the fabrication of the semiconductor device. Some nonlimiting illustrative examples of semiconductor device fabrication processing that directly contributes to the fabrication of the semiconductor device include dry etching, CVD, photoresist deposition, exposure, and development, wafer bonding processes, and/or so forth. A nonlimiting illustrative example of semiconductor device fabrication processing in the form of onsite manufacturing of chemicals used in the fabrication of the semiconductor device includes onsite manufacturing of the deionized water (e.g., UPDI as a nonlimiting illustrative example) used in the fabrication of the semiconductor device.

A nonlimiting illustrative example of semiconductor device fabrication processing in the form of processing of byproducts of the fabrication of the semiconductor device includes an F+ solidified process for removing hazardous fluorine ions from fluoride-containing waste water produced by (for example) wafer etching in a hydrofluoric acid solution. The F+ solidified process reacts the fluoride-containing waste water with calcium chloride (CaCl₂)) to form a calcium fluoride precipitate according to the reaction: Ca²⁺+2F⁻→CaF₂₍ₛ₎.

The semiconductor device fabrication processing performed at the semiconductor fabrication facility that produces the carbon dioxide-containing waste gas and the aqueous solution containing calcium ions may include a combination of processes. For example, the semiconductor device fabrication processing may include the combination of DI manufacturing that produces at least a portion of the carbon dioxide-containing waste gas, wet etching performed on semiconductor wafers using a solution of hydrofluoric acid in the manufactured DI, and F+ solidified processing of the fluoride-containing waste water from the wet etching that produces at least a portion of the aqueous solution containing calcium ions. It is to be understood that the foregoing are merely some nonlimiting illustrative examples of types of semiconductor device fabrication processing.

The carbon dioxide-containing waste gas and the aqueous alkaline solution containing calcium ions are reacted at the semiconductor fabrication facility to form solid calcium carbonate (CaCO₃), thus implementing carbon capture. The disclosed approaches advantageously leverage the aqueous alkaline byproduct of the semiconductor device fabrication processing, and optionally other such byproducts, to perform the carbon capture. Thus, additional chemicals do not need to be shipped to the semiconductor fabrication facility to perform the onsite carbon capture (or, at the least, a reduced amount of chemicals need to be shipped to the semiconductor fabrication facility to perform the onsite carbon capture).

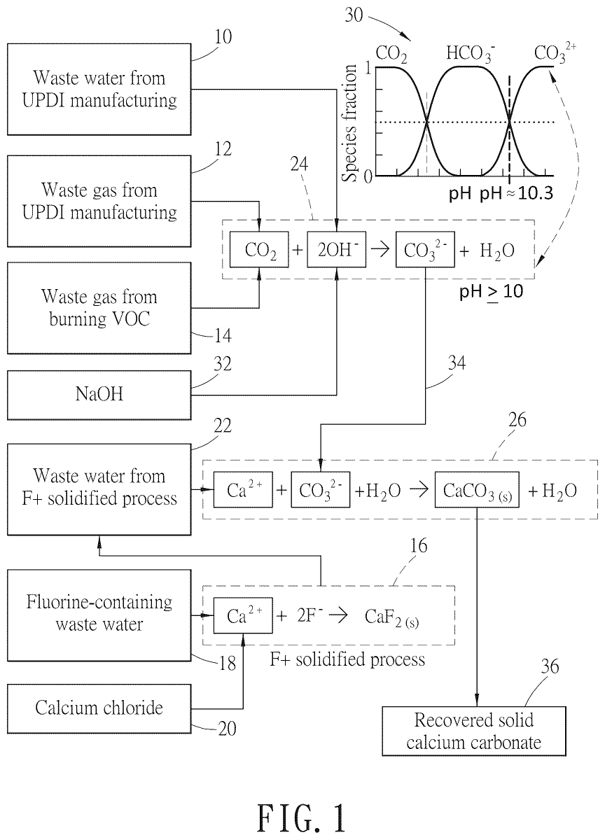

With reference to FIG. 1, a carbon capture method is diagrammatically illustrated for processing waste water and waste gases generated by semiconductor device fabrication processing performed in a semiconductor fabrication facility according to an embodiment. The carbon capture method utilizes waste water 10 from deionized water (DI) manufacturing (in the illustrative embodiment, the DI manufacturing is ultra-pure deionized water (UPDI) manufacturing, as a nonlimiting illustrative example), and waste gas 12 from the DI manufacturing. In DI-water making process, a degasifier tower is used to remove HCO₃⁻ in water. In the degasifier tower, the treated water contacts with air injected from the atmosphere by a blower, and transfers the carbon dioxide (CO₂) from the liquid phase (HCO₃⁻) to the gas phase (CO₂). The waste water 10 from the DI manufacturing provides hydroxide ions (OH⁻) for the carbon capture reactions, while the waste gas 12 from the DI manufacturing is carbon dioxide-containing waste gas from which the carbon dioxide is to be captured. In some nonlimiting examples, the waste gas 12 from the DI manufacturing contains about 1500 ppm of carbon dioxide (before carbon capture).

Another example of carbon dioxide-containing waste gas from which the carbon dioxide is to be captured is waste gas 14 from the burning of volatile organic compounds (VOCs) generated by semiconductor device fabrication processing performed in a semiconductor fabrication facility. For example, the waste gas containing volatile organic compounds may be exhaust gas from a CVD tool that uses organic precursor gas(es) in a deposition process, and/or exhaust gas from a dry etching tool that uses an organic gas as an etching agent. These are merely nonlimiting illustrative examples. In a typical VOC handling process, the waste gas containing volatile organic compounds is passed through a bed of silicon dioxide (SiO₂) which absorbs and desorbs the high-concentration volatile organic compounds from the exhaust gas. This is then sent to combustion furnace for combustion. The resulting waste gas contains a relatively high concentration of carbon dioxide, and is at a temperature of about 180˜200° C. In some nonlimiting examples, the waste gas 14 after burning contains about 15,000 ppm of carbon dioxide (before carbon capture).

An example of an aqueous solution containing calcium ions that is produced by typical semiconductor device fabrication processing performed in a semiconductor fabrication facility is the byproduct of the F+ solidified process 16 for removing hazardous fluorine ions from fluoride-containing waste water 18 produced by (for example) wafer etching in a hydrofluoric acid solution. The F+ solidified process 16 reacts the fluoride-containing waste water 18 with calcium chloride (CaCl₂)) 20 to form a calcium fluoride precipitate according to the F+ solidified process reaction:

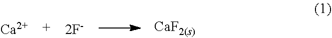

Waste water 22 from the F+ solidified process 16 contains the excess calcium ions (Ca²⁺), and hence waste water 22 from the F+ solidified process 16 constitutes an aqueous solution containing calcium ions that is produced by semiconductor device fabrication processing (i.e., the F+ solidified process 16) performed in the semiconductor fabrication facility.

The carbon capture process of FIG. 1 employs the following chemical reactions: a first reaction 24 that reacts carbon dioxide in the carbon dioxide-containing waste gas(es) 12 and 14 with hydroxide ions in an alkaline aqueous environment to convert the carbon dioxide to aqueous carbonate ions (CO₃²⁻), and a second reaction 26 that reacts the carbonate ions with aqueous calcium ions (Ca²⁺) to produce a solid calcium carbonate (CaCO₃₍ₛ₎) precipitate. The first reaction 24 is:

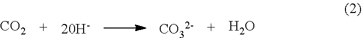

And the second reaction 26 is:

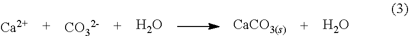 [SMILES: [Ca+2] ; "CO32-" ; O ; "CaCO3(s)" ; O]

The carbon dioxide (CO₂) reactant of the first reaction 24 is the carbon dioxide to be captured from the waste gas(es) 12 and 14, and the solid-phase calcium carbonate (CaCO₃₍ₛ₎) product of the second reaction 26 is the captured carbon in the form of calcium carbonate precipitate.

The first reaction 24 requires an aqueous alkaline solution. FIG. 1 includes a plot 30 of reaction product species fraction produced by the first reaction 24 as a function of pH. As seen in the plot 30, if the aqueous solution is acidic the dominant species fraction is carbon dioxide (CO₂), indicating the first reaction 24 does not proceed. For relatively neutral pH levels, the dominant species fraction is the polyatomic anion HCO₃⁻. For pH of at least 10, the desired carbonate (CO₃²⁻) ions become a dominant species fraction, and as seen in the plot 30 above a pH of about 10.3 the species fraction of carbonate (CO₃²⁻) ions exceeds the species fraction of polyatomic anions HCO₃⁻. Hence, the aqueous alkaline solution in which the first reaction 24 occurs in some embodiments has a pH of at least 10, and in some embodiments has pH above 10.3.

This relatively high pH (e.g., pH of at least 10 in some embodiments) is advantageously obtained at least in part by the concentration of hydroxide ions (OH⁻) in the aqueous alkaline solution. This can be obtained at least in part from the waste water 10 from the DI manufacturing. To increase the alkalinity, sodium hydroxide (NaOH) 32 optionally can be added to the aqueous alkaline solution to increase its alkalinity. Sodium hydroxide has a pH of at least 12, so that a relatively small amount of sodium hydroxide 32 can increase the alkalinity to the desired pH of 10 or higher. While sodium hydroxide 32 is illustrated in FIG. 1 as a suitable alkaline chemical to add to the aqueous alkaline solution to increase its alkalinity, other types of alkali (i.e., water-soluble) bases or solutions containing alkali bases are contemplated for this purpose.

The second reaction 26 can occur in the same aqueous alkaline solution as the first reaction 24, so that the carbon dioxide-containing waste gas 12, 14 and the aqueous alkaline solution containing calcium ions react to form solid calcium carbonate by combined operation of the first reaction 24 producing carbonate (CO₃²⁻) ions that serve as reactants in the second reaction 26, as diagrammatically indicated by the linking arrow 34 in FIG. 1. As seen in the second reaction 26 as given in Equation 3, the calcium carbonate product (CaCO₃₍ₛ₎) is a solid (as indicated by the suffixed “-₍ₛ₎”, and the calcium carbonate precipitates out of the solution to form recovered solid calcium carbonate 36. This calcium carbonate 36 (or, rather, its carbon component) constitutes the captured carbon that is removed from the carbon dioxide-containing waste gas 12, 14. Advantageously, calcium carbonate has a wide range of uses, such as being used as a building material or ingredient of cement in the construction industry, or serving as limestone aggregate in road building. Hence, the recovered solid calcium carbonate 36 is a marketable product that can be sold by the semiconductor fabrication facility to provide at least partial recompense for the costs of implementing the carbon capture (such as the cost of purchasing sodium hydroxide 32).

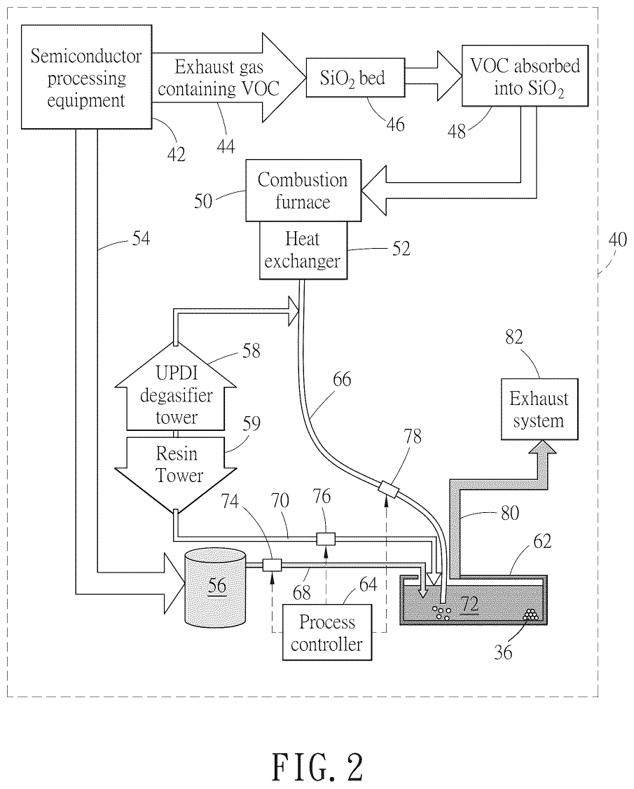

With reference now to FIG. 2, a nonlimiting illustrative embodiment of a carbon capture system of a semiconductor fabrication facility 40 is diagrammatically illustrated. The carbon capture system is typically located at the (diagrammatically indicated) semiconductor fabrication facility 40 that hosts semiconductor processing equipment 42 used to perform semiconductor device fabrication processing. The semiconductor processing equipment 42 may include, for example, dry etching tools, chemical vapor deposition (CVD) tools, physical vapor deposition (CVD) tools, and so forth which generate exhaust gas 44 that contains volatile organic compounds (VOC) comprising carbon that is to be captured. The exhaust (i.e., waste) gas 44 containing volatile organic compounds is passed through a bed 46 of silicon dioxide (SiO₂) which absorbs and desorbs the volatile organic compounds from the exhaust gas 44, resulting in silicon dioxide 48 with absorbed volatile organic compounds, which is sent to a combustion furnace 50 for combustion. The waste gas produced by the combustion (i.e., burning) contains a relatively high concentration of carbon dioxide (CO₂). In some nonlimiting examples, the waste gas after combustion contains about 15,000 ppm of carbon dioxide. The waste gas produced by the combustion is also relatively hot, e.g., exiting the combustion furnace 50 at a temperature of about 180˜200° C. in some nonlimiting embodiments. Optionally, this hot waste gas is passed through a heat exchanger 52 to cool it before being processed to capture the carbon.

The processing equipment 42 is also used to perform semiconductor device fabrication processing that produces fluoride-containing waste water 54. For example, the processing equipment 42 may include a wet etching station that performs wet etching of a semiconductor device under fabrication using a hydrofluoric acid solution, and/or a cleaning station that cleans a semiconductor device under fabrication using a cleaning fluid that contains hydrofluoric acid. As just one nonlimiting illustrative example, a buffered oxide etch containing a mixture of hydrofluoric acid and buffering ammonium fluoride (NH₄F) can be used to in silicon processing to etch films of silicon dioxide or silicon nitride. Waste water 54 from such processes contains a relatively high concentration of fluorine, which is removed by an F+ solidified process performed in a tank 56. The F+ solidified process uses calcium chloride (CaCl₂)) to capture the fluorine according to the reaction Ca²⁺+2F⁻→CaF₂₍ₛ₎. The fluorine is mostly removed from the waste water 54 as solid calcium fluoride (CaF₂) which precipitates out in the tank 56. Waste water exiting the tank 56 constitutes an aqueous solution containing calcium ions.

The illustrative semiconductor fabrication facility 40 further performs semiconductor device fabrication processing comprising deionized (DI) water fabrication (e.g., ultrapure deionized water (UPDI) fabrication in the nonlimiting illustrative example) performed at least in part using a UPDI (or, more generally, DI) degasifier tower 58 and a resin tower 59. In the degasifier tower 58, water contacts with air injected from the atmosphere by a blower (not shown), and transfers the carbon dioxide (CO₂) from the liquid phase (HCO₃⁻) to the gas phase (CO₂). The waste gas from the DI manufacturing is carbon dioxide-containing waste gas from which the carbon dioxide is to be captured. In some nonlimiting examples, the waste gas from the DI manufacturing contains about 1500 ppm of carbon dioxide (before carbon capture).

The illustrative semiconductor fabrication facility 40 further performs includes a carbon capture apparatus including a circulation tank 62 and a process controller 64. Circulation tank 62 receives carbon dioxide-containing waste gas via a pipe or tube 66. As seen in FIG. 2, the pipe or tube 66 is connected to receive the carbon dioxide-containing waste gas generated from the exhaust gas 44 by burning in the combustion furnace 50 to convert the volatile organic compounds to carbon dioxide, and optionally after cooling the gas exiting from the combustion furnace 50 using the heat exchanger 52. The waste gas from the DI manufacturing (e.g., exiting the degasifier tower 58) also contains a significant amount of carbon dioxide (e.g., about 1500 ppm of carbon dioxide in one nonlimiting illustrative example), and in the illustrative example of FIG. 2 the carbon dioxide-containing waste gas from the degasifier tower 58 is also flowed into the pipe or tube 66 for carbon capture by the carbon capture apparatus.

The carbon capture apparatus also receives an aqueous solution containing calcium ions produced by the semiconductor fabrication processing. In the illustrative example of FIG. 2, the received aqueous solution containing calcium ions includes waste water exiting from the F+ solidified process tank 56 via a pipe or tube 68, and waste water exiting from the DI manufacturing (e.g., exiting the resin tower 59) via a pipe or tube 70. In the DI water manufacturing process, acidic wastewater and alkaline wastewater will be generated during the regeneration of the resin tower 59. The alkaline wastewater can be used to adjust the pH, and the acidic wastewater can provide a solution containing calcium ions.

In the embodiment of FIG. 2, the circulation tank 62 receives the flows of aqueous solution containing calcium ions from the pipes or tubes 68 and 70. The carbon dioxide-containing waste gas is infused into the aqueous solution 72 containing calcium ions held in the circulation tank 62 by immersing the outlet of the pipe or tube 66 in the aqueous solution 72 to form a bubbler setup. Optionally, the outlet of the pipe or tube 66 immersed in the aqueous solution 72 may include a gas diffuser to improve infusion of the carbon dioxide-containing waste gas into the aqueous solution 72.

With continuing reference to FIG. 2 and further reference back to FIG. 1, the circulation tank 62 is configured to react the carbon dioxide in the waste gas delivered via pipe or tube 66 with the aqueous waste water containing calcium ions delivered by the pipes or tubes 68 and 70 by converting the carbon dioxide to aqueous carbonate ions (CO₃²⁻) by the first reaction 24: CO₂+2OH⁻→CO₃²⁻+H₂O (i.e., Equation 2); and converting the aqueous carbonate ions to calcium carbonate precipitate (CaCO₃₍ₛ₎) 36 by the second reaction 26: Ca²⁺+CO₃²⁻+H₂O→CaCO₃₍ₛ₎+H₂O (i.e., Equation 3). As discussed previously with reference to FIG. 1, the first reaction 24 operates to produce predominantly aqueous carbonate ions (CO₃²⁻) when the pH is at least 10. When the pH is at least 10.3 the fraction of aqueous carbonate ions exceeds that of polyatomic anions (HCO₃⁻), as seen in the plot 30 of FIG. 1. Accordingly, the aqueous solution 72 held by the circulation tank 62 should be an alkaline solution. In some embodiments the aqueous alkaline solution 72 has a pH of at least 10. In some embodiments, the aqueous alkaline solution 72 has a pH of at least 10.3. To maintain the aqueous solution 72 in a sufficiently alkaline state (e.g., pH≥10), the process controller 64 may control flow of the aqueous waste water containing calcium ions delivered by the pipes or tubes 68 and 70 by operating fluid flow control devices 74 and 76 installed on the respective pipes or tubes 68 and 70. Additionally or alternatively, the process controller 64 may control flow into the aqueous solution 72 of the carbon dioxide-containing waste gas via the pipe or tube 66 by a fluid flow control device 78 installed on the pipe or tube 66. The various fluid flow control devices 74, 76, and 78 may, for example, comprise valves, active pumps, ram pumps, flow constriction devices, various combinations thereof, and/or so forth.

If the pH of the aqueous solution 72 held by the circulation tank 62 cannot be maintained at a sufficiently high level (e.g., pH≥10 in some embodiments) by controlling flow of the aqueous waste water containing calcium ions delivered by the pipes or tubes 68 and 70 via respective fluid flow control devices 74 and 76, then in some embodiments an alkaline additive such as sodium hydroxide (NaOH) or another alkali base may be added to the aqueous solution 72 for this purpose. Such an alkaline additive may be delivered manually, or via a further pipe or tube governed by a suitable fluid flow control devices controlled by the process controller 64 (features not shown in FIG. 2).

The process controller 64 may be optional—in other embodiments the various fluid flow control devices 74, 76, and 78 (and any further fluid flow control device for controlling a pipe or tube delivering an alkaline additive) may be manually operated devices (e.g., pumps with manually adjusted valves and/or flow constrictors). If provided, the process controller 64 may be implemented by way of nonlimiting illustrative example as an electronic controller (e.g., having a microprocessor or microcontroller) connected by wires or by wireless communication with the various fluid flow control devices 74, 76, and 78. Although not shown, a pH sensor may be disposed in the circulation tank 62 to monitor the pH of the aqueous alkaline solution 72, and pH measurements by the pH sensor may be inputs to the process controller 64. (In a manual embodiment, the pH sensor would suitably be displayed in a human-viewable manner to provide information to semiconductor fabrication facility workers to assist in making manual adjustments).

The carbon capture system further includes an exhaust line 80 that exhausts ambient gas in the tank above the aqueous alkaline solution 72 to an exhaust system 82 that exhausts to a suitable outlet such as the ambient air outside of the semiconductor fabrication facility 40. The exhaust system 82 may, by way of nonlimiting illustrative example, include a volatile organic compounds exhaust (VEX) system, an alkali exhaust (AEX) system, or a combination thereof. Optionally, a carbon dioxide sensor (not shown) may be included on the exhaust line 80 to monitor the concentration of carbon dioxide in the exhausted gas (e.g., measured as ppm) to document the effectiveness of the carbon capture.

In the embodiment of FIG. 2, the reactor for performing the carbon capture reactions (i.e., Equations 1 and 2) comprises the circulation tank 62. In this reactor, the contact area between the carbon dioxide-containing waste gas delivered by the pipe or tube 66 and the aqueous alkaline solution 72 is relatively limited, being provided by the infusion of the waste gas into the aqueous alkaline solution 72 by immersion of the outlet of the pipe or tube 66 in the aqueous alkaline solution 72, optionally assisted by a diffuser installed at the outlet of the pipe or tube 66.

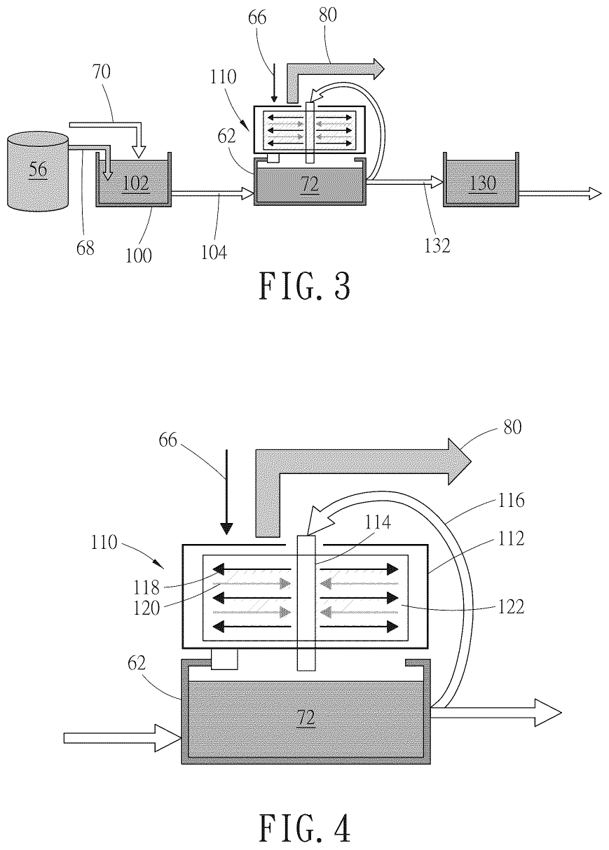

With reference now to FIG. 3, a nonlimiting illustrative embodiment of a carbon capture system of a semiconductor fabrication facility 40 is diagrammatically illustrated. The carbon capture system of FIG. 3 also receives carbon dioxide-containing waste gas via the pipe or tube 66, and also receives the aqueous solution containing calcium ions including the waste water exiting from the F+ solidified process tank 56 received via the pipe or tube 68 and the waste water exiting from the DI manufacturing received via the pipe or tube 70. The carbon capture system of FIG. 3 also includes the exhaust line 80. Although not shown in FIG. 3, the carbon capture system of FIG. 3 is suitably located in a semiconductor fabrication facility analogous to the semiconductor fabrication facility 40 of FIG. 2, and that facility suitably includes the various elements 42, 44, 46, 48, 50, 52, 54, 56, and 58 as described with reference to FIG. 2. Still further, although not shown in FIG. 3 the carbon capture system of FIG. 3 may include the process controller 64 controlling fluid flow control devices analogous to the fluid flow control 74, 76, and 78 of FIG. 2.

The carbon capture system of FIG. 3 provides for enhanced control of the pH of the aqueous alkaline solution 72 in the circulation tank 62 by the addition of an upstream Ca⁺ buffer tank 100 that receives the waste water exiting from the F+ solidified process tank 56 via the pipe or tube 68, and the waste water exiting from the DI manufacturing via the pipe or tube 70. The Ca⁺ buffer tank 100 holds an aqueous alkaline solution 102 containing calcium ions. As the carbon capture reactions (i.e., Equations 1 and 2) are not occurring in the Ca⁺ buffer tank 100, this tank can be used solely for controlling the pH of the aqueous alkaline solution 102, e.g., by controlling flows through the pipes or tubes 68 and 70 and/or adding an alkaline additive such as sodium hydroxide (NaOH) or another alkali base to increase the pH of the aqueous alkaline solution 102. In some embodiments, the aqueous alkaline solution 102 in the Ca⁺ buffer tank 100 has a pH of at least 10. In some embodiments, the aqueous alkaline solution 102 in the Ca⁺ buffer tank 100 has a pH of at least 10.3.

The aqueous alkaline solution 102 containing calcium ions held in the Ca⁺ buffer tank 100 is transferred (i.e., flows) to the downstream circulation tank 62 via a pipe or tube 104. The rate of flow through the pipe or tube 104 can be controlled to control the level of the aqueous alkaline solution 72 in the circulation tank 62. The circulation tank 62 of FIG. 3 is analogous to the circulation tank 62 of FIG. 2. As previously noted, in the embodiment of FIG. 2 the reactor for performing the carbon capture reactions comprises the circulation tank 62, and hence has a limited contact area between the carbon dioxide-containing waste gas delivered by the pipe or tube 66 and the aqueous alkaline solution 72 contained in the circulation tank 62.

With continuing reference to FIG. 3 and with further reference to FIG. 4, in the embodiment of FIG. 3 a larger contact area between the carbon dioxide-containing waste gas delivered by the pipe or tube 66 and the aqueous alkaline solution 72 contained in the circulation tank 62 is obtained by providing a reactor that includes the circulation tank 62 and that further includes a gas aeration atomizer 110. FIG. 4 shows an enlarged isolation view of the gas aeration atomizer 110. As labeled only in FIG. 4, the gas aeration atomizer 110 includes an enclosure 112 and a liquid distributer 114. A pipe or tube 116 having a pump (not shown) transfers the aqueous alkaline solution 72 to an upper end of the liquid distributor 114, which rotates or spins, and has openings along its sidewalls from which the aqueous alkaline solution 72 is expelled as outwardly directed aqueous alkaline solution (diagrammatically indicated by outwardly directed arrows 118). The pipe or tube 66 delivers the carbon dioxide-containing waste gas into the upper end of the enclosure 112 where it flows inward as diagrammatically indicated by inwardly directed arrows 120. Thus, the liquid and gas are in intimate contact within a gas-liquid mixing volume 122 inside the enclosure 112. This provides the advantageously large contact volume 122 between the carbon dioxide-containing waste gas delivered by the pipe or tube 66 and the aqueous alkaline solution 72 contained in the circulation tank 62. Furthermore, as seen in FIG. 4, the exhaust line 80 is connected near the top of the enclosure 112.

With returning focus on FIG. 3, a further feature of the carbon capture system of FIG. 3 is inclusion of a sedimentation tank 130 which receives outward flow of the aqueous alkaline solution 72 contained in the circulation tank 62 via a pipe or tube 132. The sedimentation tank 130 advantageously facilitates solid-liquid separation for recovery of the solid calcium carbonate precipitate (CaCO₃), which can then be sold to the construction industry or another commercial industry that utilizes calcium carbonate.

In the following, some nonlimiting illustrative examples of some operating parameters for the carbon capture system of FIG. 3 are disclosed.

In some nonlimiting illustrative embodiments, the pipe or tube 68 introduces the waste water exiting from the F+ solidified process tank 56 with a concentration of calcium ions (Ca⁺) of at least 180 ppm into the buffer tank 100.

In some nonlimiting illustrative embodiments, the pipe or tube 70 introduces alkaline waste water exiting from the resin tower 59 with a pH of at least 8. In the DI water manufacturing process, acidic wastewater and alkaline wastewater are generated during the regeneration of the resin tower 59, and the alkaline wastewater from the resin tank 59 delivered via the pipe or tube 70 can be used to adjust the pH of the aqueous alkaline solution 72 in the circulation tank 62.

In some nonlimiting illustrative embodiments, the pipe or tube 66 introduces the carbon dioxide-containing waste gas with a concentration of carbon dioxide (CO₂) of at least 1500 ppm.

In some nonlimiting illustrative embodiments, the gas aeration atomizer 110 operates at a pressure in the gas-liquid mixing volume 122 of at least 0.5 atmosphere.

In some nonlimiting illustrative embodiments, the process controller may further control a rotation speed of the gas aeration atomizer 110.

In some nonlimiting illustrative embodiments, a filter or filters (not shown) may be included at inlets and/or outlets of one or more of the pipes or tubes 66, 68, 70, 104, 116, and/or 132.

As previously described with reference to FIG. 2, the carbon capture system of FIG. 3 may include the process controller 64 and suitable fluid flow control devices (e.g., pumps, ram pumps, constriction devices, valves, et cetera) to manage the flow rates through the various pipes or tubes 66, 68, 70 as well as through the various pipes or tubes 104, 116, 132 to control the carbon capture process, optionally based on sensor data such as pH of the aqueous alkaline solution 102 in the Ca⁺ buffer tank 100 and the aqueous alkaline solution 72 in the circulation tank 62 using pH sensors (not shown) in the respective tanks 100 and 72; and/or calcium ion concentration measured in one or both tanks 100 and/or 72 and/or 130 using a calcium concentration sensor (or sensors). In some embodiments, one or more thermal sensors may also be provided, e.g., to monitor temperature of the waste gas coming out of the combustion furnace 50 and/or out of the heat exchanger 52.

In the following, some further embodiments are described.

In a nonlimiting illustrative embodiment, a method of processing waste material generated by a semiconductor fabrication facility includes: performing semiconductor device fabrication processing that produces a carbon dioxide-containing waste gas and an aqueous solution containing calcium ions; and reacting the carbon dioxide-containing waste gas and the aqueous solution containing calcium ions to form solid calcium carbonate.

In a nonlimiting illustrative embodiment, a method of processing waste material generated by a semiconductor fabrication facility includes: burning volatile organic compounds of an exhaust gas produced by the semiconductor fabrication facility to generate carbon dioxide-containing waste gas; reacting fluorine-containing waste water produced by the semiconductor fabrication facility with calcium chloride to generate solid calcium fluoride and an aqueous solution containing calcium ions; and capturing carbon from the exhaust gas by reacting the carbon dioxide-containing waste gas and the aqueous solution containing calcium ions to form solid calcium carbonate.

In a nonlimiting illustrative embodiment, a carbon capture apparatus for a semiconductor fabrication facility includes: a buffer tank operatively connected to receive aqueous waste water from a fluorine removal system of the semiconductor fabrication facility that reacts fluorine-containing waste water with calcium chloride, the buffer tank holding aqueous alkaline waste water containing calcium ions; and a reactor configured to capture carbon from waste gas generated by the semiconductor fabrication facility by reacting carbon dioxide in the waste gas with the aqueous alkaline waste water containing calcium ions which is transferred to the reactor from the buffer tank to produce solid calcium carbonate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of processing waste material generated by a semiconductor fabrication facility, the method comprising:
performing semiconductor device fabrication processing that produces a carbon dioxide-containing waste gas and an aqueous solution containing calcium ions; and
reacting the carbon dioxide-containing waste gas and the aqueous solution containing calcium ions to form solid calcium carbonate.

2. The method of claim 1, wherein the semiconductor device fabrication processing includes:
performing at least one first semiconductor device fabrication processing that produces an exhaust gas containing volatile organic compounds; and
burning the volatile organic compounds to generate the carbon dioxide-containing waste gas.

3. The method of claim 2, wherein the first semiconductor device fabrication processing further includes:
absorbing the volatile organic compounds from the exhaust gas into silicon dioxide;
wherein the burning includes burning the volatile organic compounds absorbed into the silicon dioxide to generate the carbon dioxide-containing waste gas.

4. The method of claim 2, wherein the at least one first semiconductor device fabrication processing includes at least one of:
performing etching of material of a semiconductor device under fabrication using a dry etching system and at least one organic reactant gas; or
performing deposition of material on a semiconductor device under fabrication using a deposition system and at least one organic gas.

5. The method of claim 2, wherein the first semiconductor device fabrication processing further includes:
absorbing the volatile organic compounds from the exhaust gas into silicon dioxide;
wherein the burning includes burning the volatile organic compounds absorbed into the silicon dioxide to generate the carbon dioxide-containing waste gas.

6. The method of claim 1, wherein the semiconductor device fabrication processing includes:
performing at least one second semiconductor device fabrication processing that produces fluorine-containing waste water; and
reacting the fluorine-containing waste water with calcium chloride to generate solid calcium fluoride and the aqueous solution containing calcium ions.

7. The method of claim 6, wherein the at least one second semiconductor device fabrication processing includes performing etching and/or cleaning of a semiconductor device under fabrication using a hydrofluoric acid solution.

8. The method of claim 6, further comprising:
increasing alkalinity of the aqueous solution containing calcium ions by adding sodium hydroxide and/or water output by a deionized water manufacturing process to the aqueous solution containing calcium ions output by the reacting of the fluorine-containing waste water with calcium chloride.

9. The method of claim 6, further comprising:
increasing alkalinity of the aqueous solution containing calcium ions in a buffer tank;
transferring the aqueous solution containing calcium ions from the buffer tank to a circulation tank;
wherein the reacting of the carbon dioxide-containing waste gas is with the aqueous solution containing calcium ions in the circulation tank.

10. The method of claim 9, wherein the reacting of the carbon dioxide-containing waste gas with the aqueous solution containing calcium ions in the circulation tank is performed using a gas aeration atomizer into which the carbon dioxide-containing waste gas is input and into which the aqueous solution containing calcium ions is pumped from the circulation tank.

11. The method of claim 1, wherein the semiconductor device fabrication processing includes:
manufacturing deionized water, wherein at least one of:
(i) the carbon dioxide-containing waste gas includes carbon dioxide vapor output by the manufacturing of the deionized water; and/or
(ii) the aqueous solution containing calcium ions includes waste water output by the manufacturing of the deionized water.

12. The method of claim 1, wherein the reacting of the carbon dioxide-containing waste gas and the aqueous solution containing calcium ions is performed using a circulation tank holding the aqueous solution containing calcium ions, and the method further includes:
transferring waste water from the circulation tank to a sedimentation tank; and
collecting the solid calcium carbonate in the sedimentation tank.

13. The method of claim 1, wherein the aqueous solution containing calcium ions has a pH of at least 10.

14. A method of processing waste material generated by a semiconductor fabrication facility, the method comprising:
burning volatile organic compounds of an exhaust gas produced by the semiconductor fabrication facility to generate carbon dioxide-containing waste gas;
reacting fluorine-containing waste water produced by the semiconductor fabrication facility with calcium chloride to generate solid calcium fluoride and an aqueous solution containing calcium ions; and
capturing carbon from the exhaust gas by reacting the carbon dioxide-containing waste gas and the aqueous solution containing calcium ions to form solid calcium carbonate.

15. The method of claim 14, further comprising:
absorbing the volatile organic compounds from the exhaust gas into silicon dioxide;
wherein the burning includes burning the volatile organic compounds absorbed into the silicon dioxide to generate the carbon dioxide-containing waste gas.

16. The method of claim 14, further comprising:
increasing alkalinity of the aqueous solution containing calcium ions in a buffer tank to make the aqueous solution containing calcium ions an aqueous alkaline solution containing calcium ions;
transferring the aqueous alkaline solution containing calcium ions from the buffer tank to a circulation tank;
wherein the reacting is performed using a gas aeration atomizer into which the carbon dioxide-containing waste gas is input and into which the aqueous alkaline solution containing calcium ions is pumped from the circulation tank.

17. The method of claim 16, wherein the alkalinity of the aqueous alkaline solution containing calcium ions in the buffer tank is increased by adding water output by a deionized water manufacturing process to the buffer tank, and the method further comprises:
adding carbon dioxide vapor output by the manufacturing of the deionized water to the carbon dioxide-containing waste gas.

18. A carbon capture apparatus for a semiconductor fabrication facility, the carbon capture apparatus comprising:
a buffer tank operatively connected to receive aqueous waste water from a fluorine removal system of the semiconductor fabrication facility that reacts fluorine-containing waste water with calcium chloride, the buffer tank holding aqueous alkaline waste water containing calcium ions; and
a reactor configured to capture carbon from waste gas generated by the semiconductor fabrication facility by reacting carbon dioxide in the waste gas with the aqueous alkaline waste water containing calcium ions which is transferred to the reactor from the buffer tank to produce solid calcium carbonate.

19. The carbon capture apparatus of claim 18, wherein the reactor is configured to react the carbon dioxide in the waste gas with the aqueous alkaline waste water containing calcium ions by converting the carbon dioxide (CO₂) to aqueous carbonate ions (CO₃²⁻) by the reaction: 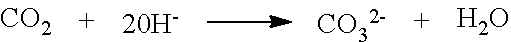
and converting the aqueous carbonate ions (CO₃²⁻) to calcium carbonate precipitate (CaCO₃₍ₛ₎) by the reaction: 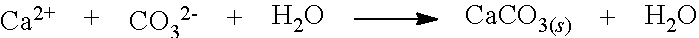 [SMILES: [Ca+2] ; "CO32-" ; O ; "CaCO3(s)" ; O]
wherein the configuration of the reactor includes maintaining liquid contained in the reactor at a pH of at least 10.

20. The carbon capture apparatus of claim 18, wherein the reactor includes:
a circulation tank operatively connected to receive the aqueous waste water from the buffer tank; and
a gas aeration atomizer connected to receive the waste gas generated by the semiconductor fabrication facility and the aqueous alkaline solution pumped into the gas aeration atomizer from the circulation tank.
